(19) United States
(12) Patent Application Publication
(10) Pub. No.: US 2025/0311460 A1
(43) Pub. Date: Oct. 2, 2025

(54) IMAGE SENSING DEVICE

(71) Applicant: SK hynix Inc., Icheon-si (KR)

(72) Inventor: Dong Ho HA, Icheon-si (KR)

(21) Appl. No.: 18/908,647

(22) Filed: Oct. 7, 2024

(30) Foreign Application Priority Data
Mar. 28, 2024 (KR) 10-2024-0042574

(51) Int. Cl. H01L 27/146

(52) U.S. Cl. CPC H10F 39/807; H10F 39/182; H10F 39/8053

(57) ABSTRACT

An image sensing device is provided to include a first pixel configured to overlap a first optical filter that transmits light of a first color and configured to generate photocharges in response to the light of the first color; a second pixel disposed apart from the first pixel in a first direction and configured to overlap a second optical filter that transmits light of a second color and to generate photocharges in response to the light of the second color; a first pixel isolation structure surrounding the first pixel to isolate the first pixel and the second pixel from each other and configured to receive a first bias voltage; and a second pixel isolation structure surrounding the second pixel to optically isolate the first pixel and the second pixel from each other and configured to receive a second bias voltage different from the first bias voltage.

### CROSS-REFERENCE TO RELATED APPLICATION

This patent document claims the priority and benefits of Korean patent application No. 10-2024-0042574, filed on Mar. 28, 2024, the disclosure of which is incorporated herein by reference in its entirety as part of the disclosure of this patent document.

### TECHNICAL FIELD

The technology and embodiments disclosed in this patent document generally relate to an image sensing device, and more particularly to an image sensing device including a structure capable of reducing noise of pixels.

### BACKGROUND

An image sensing device is a device for capturing at least one image using semiconductor characteristics that react to light incident thereon to produce an image. In recent times, with the increasing development of information technology (IT) industries and related technologies, the demand for high-quality and high-performance image sensing devices has been rapidly increasing in various electronic devices, for example, smartphones, digital cameras, etc.

Image sensing devices may be broadly classified into CCD (Charge Coupled Device)-based image sensing devices and CMOS (Complementary Metal Oxide Semiconductor)-based image sensing devices. Unlike in the past, CMOS image sensing devices have been intensively researched and rapidly come into widespread use.

### SUMMARY

In accordance with an embodiment of the disclosed technology, an image sensing device may include: a first pixel configured to overlap a first optical filter that transmits light of a first color and configured to generate photocharge in response to the light of the first color; a second pixel disposed apart from the first pixel in a first direction and configured to overlap a second optical filter that transmits light of a second color different from the first color and to generate photocharge in response to the light of the second color; a first pixel isolation structure surrounding the first pixel to isolate the first pixel and the second pixel from each other and configured to receive a first bias voltage; and a second pixel isolation structure surrounding the first pixel to isolate the first pixel and the second pixel from each other and configured to receive a second bias voltage different from the first bias voltage.

In some implementations, the image sensing device may further include: a first bias contact configured to transfer the first bias voltage to the first pixel isolation structure; and a second bias contact configured to transfer the second bias voltage to the second pixel isolation structure.

In some implementations, the image sensing device may further include: a third pixel configured to have a third optical filter that transmits light of a third color different from each of the first color and the second color, the third pixel disposed apart from the first pixel in a second direction different from the first direction; and a third pixel isolation structure surrounding the third pixel and configured to receive a third bias voltage, wherein the third bias voltage is different from each of the first bias voltage and the second bias voltage.

In some implementations, the image sensing device may further include: a third bias contact configured to transfer the third bias voltage to the third pixel isolation structure.

In some implementations, the first color may be green, the second color may be red, and the third color may be blue.

In some implementations, the image sensing device may further include: a pixel insulation structure disposed between the first pixel isolation structure and the second pixel isolation structure and configured to electrically isolate the first pixel isolation structure and the second pixel isolation structure from each other.

In some implementations, a magnitude of the first bias voltage may be greater than a magnitude of the second bias voltage in response to a dark current of the first pixel being greater than a dark current of the second pixel.

In some implementations, a magnitude of the first bias voltage may be smaller than a magnitude of the second bias voltage in response to a temperature of the first pixel being higher than a temperature of the second pixel.

In some implementations, the image sensing device may further include: a third pixel configured to overlap a third optical filter that transmits light of the first color and disposed apart from the first pixel in a second direction different from the first direction; a fourth pixel configured to overlap a fourth optical filter that transmits light of the second color and disposed apart from the second pixel in the second direction; a third pixel isolation structure surrounding the third pixel and configured to receive the first bias voltage; and a fourth pixel isolation structure surrounding the fourth pixel and configured to receive the second bias voltage.

In some implementations, the first pixel isolation structure and the third pixel isolation structure may be included in a first pixel group isolation structure and disposed to be in contact with each other; and the second pixel isolation structure and the fourth pixel isolation structure may be included in a second pixel group isolation structure and disposed to be in contact with each other.

In some implementations, the image sensing device may further include: a pixel insulation structure disposed between the first pixel group isolation structure and the second pixel group isolation structure to electrically isolate the first pixel group isolation structure and the second pixel group isolation structure from each other.

In some implementations, the first pixel and the third pixel may be read out within a first time period, and the second pixel and the fourth pixel may be read out within a second time period; and the first bias voltage may be applied to the first pixel group isolation structure during the first time period, and the second bias voltage may be applied to the second pixel group isolation structure during the second time period, wherein an end point of the first time period is earlier than a starting point of the second time period.

In some implementations, the first bias voltage may be applied to the first pixel isolation structure during a readout of the first pixel; and the second bias voltage may be applied to the second pixel isolation structure during a readout of the second pixel.

In accordance with another embodiment of the disclosed technology, an image sensing device may include: a first photoelectric conversion element disposed in a semiconductor substrate and configured to generate photocharges in response to incident light; a second photoelectric conversion element disposed in the semiconductor substrate and spaced apart from the first photoelectric conversion element in a first direction, the second photoelectric conversion element configured to generate photocharges in response to the incident light; a first optical filter disposed on a back surface of the semiconductor substrate upon which the incident light is incident and overlapping the first photoelectric conversion element, the first optical filter configured to transmit light of a first color from among the incident light; a second optical filter disposed on the back surface of the semiconductor substrate and overlapping the second photoelectric conversion element, the second optical filter configured to transmit light of a second color different from the first color from among the incident light; a first pixel isolation structure recessed into the semiconductor substrate and surrounding the first photoelectric conversion element; and a second pixel isolation structure recessed into the semiconductor substrate and surrounding the second photoelectric conversion element, wherein the first pixel isolation structure is configured to receive a first bias voltage; and the second pixel isolation structure is configured to receive a second bias voltage different from the first bias voltage.

In some implementations, the image sensing device may further include: a third photoelectric conversion element disposed within the semiconductor substrate and spaced apart from the first photoelectric conversion element in a second direction different from the first direction, the third photoelectric conversion element configured to generate photocharges in response to the incident light; and a third optical filter disposed on the back surface of the semiconductor substrate and overlapping the third photoelectric conversion element, the third optical filter configured to transmit light of a third color different from each of the first color and the second color from among the incident light.

In some implementations, the first color may be green, the second color may be red, and the third color may be blue.

In some implementations, the image sensing device may further include: a third pixel isolation structure recessed into the semiconductor substrate and surrounding the third photoelectric conversion element, the third pixel isolation structure spaced apart from the first pixel isolation structure in the second direction, wherein the third pixel isolation structure is configured to receive a third bias voltage different from each of the first bias voltage and the second bias voltage.

In some implementations, the image sensing device may further include: a pixel insulation structure disposed between the first pixel isolation structure and the second pixel isolation structure to electrically isolate the first pixel isolation structure and the second pixel isolation structure from each other.

In accordance with another embodiment of the disclosed technology, an image sensing device may include: a first pixel configured to generate an electrical signal in response to light of a first color; a second pixel spaced apart from the first pixel and configured to generate an electrical signal in response to light of a second color; a first pixel isolation structure configured to receive a first bias voltage and surrounding the first pixel; and a second pixel isolation structure spaced apart from the first pixel isolation structure, and configured to receive a second bias voltage and surrounding the second pixel.

In accordance with another embodiment of the disclosed technology, an image sensing device may include: a first pixel group including a plurality of first pixels, each first pixel configured to generate an electrical signal in response to light of a first color; a second pixel group including a plurality of second pixels, each second pixel configured to generate an electrical signal in response to light of second color; a first pixel group isolation structure configured to receive a first bias voltage and surrounding the plurality of first pixels; and a second pixel group isolation structure spaced apart from the first pixel group isolation structure and surrounding the plurality of second pixels, the second pixel group isolation structure configured to receive a second bias voltage.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device according to embodiments of the disclosed technology.

FIG. 2 is a schematic diagram illustrating an example of a pixel array shown in FIG. 1 according to embodiments of the disclosed technology.

FIG. 3 is a schematic diagram illustrating an example of a pixel group shown in FIG. 2 according to a first embodiment of the disclosed technology.

FIG. 4 is a schematic diagram illustrating an example of the pixel group shown in FIG. 2 according to a second embodiment of the disclosed technology.

FIG. 5A is a schematic diagram illustrating an example in which a bias voltage is applied to a first pixel group shown in FIG. 3 according to embodiments of the disclosed technology.

FIG. 5B is a schematic diagram illustrating an example in which a bias voltage is applied to a second pixel group shown in FIG. 4 according to embodiments of the disclosed technology.

FIG. 6 is a cross-sectional view illustrating an example of the pixel group taken along the line A-A′ of FIG. 3 according to embodiments of the disclosed technology.

FIG. 7 is a cross-sectional view illustrating another example of the pixel group taken along the line A-A′ of FIG. 3 according to embodiments of the disclosed technology.

FIG. 8 is a cross-sectional view illustrating an example of the pixel group taken along the line B-B′ of FIG. 4 according to embodiments of the disclosed technology.

FIG. 9 is a cross-sectional view illustrating another example of the pixel group taken along the line B-B′ of FIG. 4 according to embodiments of the disclosed technology.

FIG. 10 is a circuit diagram illustrating an example of a circuit configured to model each pixel shown in FIG. 2 according to embodiments of the disclosed technology.

FIG. 11A is a timing diagram illustrating example levels of first to fourth bias signals applied to first to fourth pixel isolation structures shown in FIG. 5A according to embodiments of the disclosed technology.

FIG. 11B is a timing diagram illustrating example levels of first to fourth bias signals applied to first to fourth pixel group isolation structures shown in FIG. 5B according to embodiments of the disclosed technology.

### DETAILED DESCRIPTION

This patent document provides embodiments and examples of an image sensing device including a structure capable of reducing noise of pixels. The disclosed features of such an image sensing device may be implemented in various configurations to substantially address one or more technical or engineering issues and to mitigate limitations or disadvantages encountered in some image sensing devices in the art. Some embodiments of the disclosed technology relate to an image sensing device with improved image quality by uniformly correcting different noise components for each pixel depending on a wavelength range (or color) of incident light. In recognition of the issues in the art, the image sensing device based on some implementations of the disclosed technology can reduce noise of pixels, and can reduce noise deviation that may occur between pixels that transmit light of different wavelengths. In addition, the disclosed technology can provide the image sensing device which reduces power consumption by designing timing points at which different bias voltages are applied to the pixels that respectively transmit light beams of different wavelengths.

Reference will now be made in detail to the embodiments of the disclosed technology, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

Hereinafter, various embodiments will be described with reference to the accompanying drawings. However, it should be understood that the disclosed technology is not limited to specific embodiments or examples as described, but various modifications, equivalents and/or alternatives of the embodiments as described may be made based on the disclosure of this patent document. The embodiments of the disclosed technology may be used in various ways to provide a variety of effects directly or indirectly.

Various embodiments of the disclosed technology relate to an image sensing device with improved image quality by uniformly correcting different noise components for each pixel depending on a wavelength range (or color) of incident light.

It is to be understood that both the foregoing general description and the following detailed description of the disclosed technology are illustrative and explanatory and are intended to provide further explanation of the disclosure as claimed.

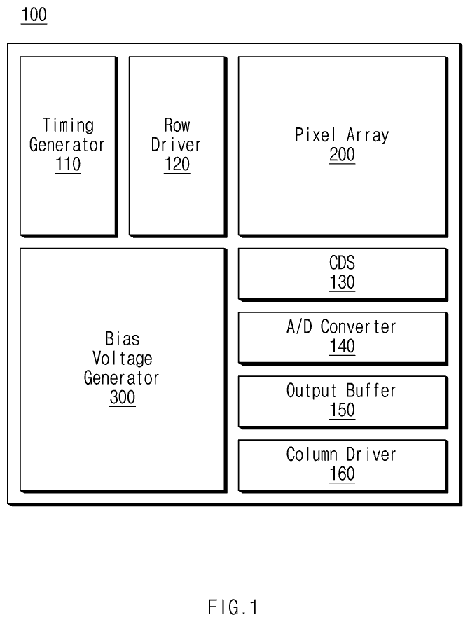

FIG. 1 is a block diagram illustrating an example of an image sensing device 100 according to embodiments of the disclosed technology.

Referring to FIG. 1, the image sensing device 100 based on some implementations of the disclosed technology may include a timing generator 110, a row driver 120, a bias voltage generator 300, a pixel array 200, a correlated double sampler (CDS) 130, an analog-to-digital converter (ADC) 140, an output buffer 150, and a column driver 160. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

The timing generator 110 may provide timing signals and control signals to at least one of the row driver 120, the correlated double sampler (CDS) 130, the ADC 140, the output buffer 150, and the column driver 160. In some implementations, the timing generator 110 may also provide a timing signal and a control signal to the bias voltage generator 300.

The row driver 120 may activate the pixel array 200 to perform specific operations on pixels included in a corresponding row based on the timing and control signals received from the timing generator 110.

In some implementations, the row driver 120 may select at least one pixel arranged in at least one row of the pixel array 200, and may provide the selected pixel with a control signal for performing a specific operation. The row driver 120 may generate a row selection signal to select at least one row from among a plurality of rows. When the row driver 120 selects a specific row from among the plurality of rows to perform a specific operation, the row driver 120 may not perform the specific operation on a row adjacent to the selected specific row.

The pixels of the row selected by the row driver 120 may sequentially transfer analog reference signals and image signals to the correlated double sampler (CDS) 130. The reference signal may be an electrical signal provided to the CDS 130 when a floating diffusion region of each pixel is reset to a power-supply voltage VDD. The image signal may be an electrical signal provided to the CDS 130 when photocharges generated by each pixel are accumulated in the floating diffusion region (FD) region.

The reference signal may be a signal indicating unique pixel noise of each pixel, and the reference signal and the image signal may be collectively referred to as a pixel signal as necessary.

The pixel array 200 may include a plurality of pixels arranged in a plurality of rows and a plurality of columns. The plurality of pixels may be connected to the row driver 120 through a plurality of row lines extending in the row direction. The plurality of pixels may be connected to the CDS 130 through a plurality of column lines extending in the column direction. The pixel array 200 may include at least one pixel arranged in the row direction and the column direction. For example, the pixel array 200 may be arranged in a two-dimensional (2D) pixel array in which a plurality of unit pixels are arranged in rows and columns.

The plurality of unit pixels included in the pixel array 200 may convert optical signals into electrical signals, and may be connected to a specific internal pixel circuit. Each of the plurality of unit pixels may be surrounded by a pixel isolation structure. The pixel isolation structure can optically isolate adjacent pixels from each other, and can reduce noise of each pixel upon receiving a predetermined bias voltage.

In various implementations, each pixel may be configured to include an optical filter that transmits light of a first color and a photoelectric conversion element disposed to receive the light of the first color from the optical filter and configured to generate photocharge in response to the received light of the first color. Specifically, each of the plurality of unit pixels included in the pixel array 200 may include at least one photoelectric conversion element or photodetector for detecting incident light and an optical filter disposed in the path of the incident light to filter the incident light to be received by the photoelectric conversion element so that light having penetrated the optical filter is incident to and detected by the photoelectric conversion element, and each optical filter may transmit light of a specific wavelength range or light of a specific color. For example, an optical filter configured to transmit green light may transmit a greater amount of light than an optical filter configured to transmit red light, and an optical filter configured to transmit red light may transmit a greater amount of light than an optical filter configured to transmit blue light. Light beams having different wavelength ranges may have different penetration depths into a semiconductor substrate that may form a portion of the pixel array 200. For example, the penetration depth of green light may be greater than that of blue light, and the penetration depth of green light may be smaller than that of red light. In association with the above-described penetration depths, the depths at which light beams of the respective colors are concentrated may be different from each other. The amount of light incident upon the photoelectric conversion element may vary depending on the penetration depth.

The pixel array 200 may receive a pixel control signal including a row selection signal, a pixel reset signal, a row transfer signal, etc. from the row driver 120. At least one pixel included in the row that is selected by the row driver 120 according to the pixel control signal may perform a specific operation in response to the row selection signal, the pixel reset signal, and the row transfer signal.

The bias voltage generator 300 may apply a bias voltage (e.g., a negative (−) bias voltage) to each of the plurality of pixel isolation structures that may be included in the pixel array 200. The bias voltage generator 300 may determine at least one of the magnitude of the bias voltage and a timing point at which the bias voltage is applied to each pixel isolation structure. For example, the bias voltage generator 300 may determine the bias voltage applied to a pixel isolation structure surrounding a pixel having a higher temperature than adjacent pixels to be lower than the bias voltage applied to a pixel isolation structure surrounding peripheral pixels. For example, the temperature of a pixel may experimentally measured in advance for each pixel position. For example, a pixel with a relatively large amount of incident light may generate much more photocharges than a pixel with a relatively small amount of incident light. Due to the heat generated by a photocharge generation reaction, a pixel with a relatively large amount of incident light may have a higher temperature than an adjacent pixel with a relatively small amount of incident light. For example, a pixel including an optical filter configured to transmit red light may have a lower temperature than a pixel including an optical filter configured to transmit green light. For example, a pixel including an optical filter configured to transmit red light may have a higher temperature than a pixel including an optical filter configured to transmit blue light. A temperature difference among the optical filters depending on the colors of light beams having penetrated the optical filters can be determined experimentally, and the magnitude of the bias voltage applied by the bias voltage generator 300 to each pixel isolation structure can be determined according to the experimental results.

In addition to the temperature, there may exist other factors to affect the magnitudes of the bias voltages applied by the bias voltage generator 300. For example, the degree of noise generation in different pixels that generate electrical signals by sensing light beams of different colors may vary depending on the temperature as well as other factors (e.g., height, thickness, width, and material properties of the optical filters). Thus, the magnitudes of bias voltages applied by the bias voltage generator 300 may vary depending on the embodiments.

The CDS 130 may receive the reference signal and the image signal, each of which corresponds to the columns of the pixel array 200, and may sample levels of the reference signal and the image signal. In the image sensing device designed to use CMOS(s), the CDS 130 may sample a pixel signal twice to remove a difference between these two samples, and may perform correlated double sampling to remove undesired offset values of pixels such as fixed noise. For example, the CDS 130 may compare pixel output voltages obtained before and after photocharges generated by incident light are accumulated in the floating diffusion region to remove undesired offset values, so that the pixel output voltages based on the incident light can be measured.

The CDS 130 may transmit reference signals and image signals, which are generated in columns based on a timing signal and a control signal of the timing generator 110, to the ADC 140 as CDS signals.

The ADC 140 may convert analog CDS signals received from the CDS 130 into digital signals, and may output the resultant digital signals.

The output buffer 150 may temporarily hold and output digital signals provided from the ADC 140.

The column driver 160 may select columns from the output buffer 150 based on a timing signal and a control signal of the timing generator 110, and may control the temporarily held digital signals to be output according to the selection order.

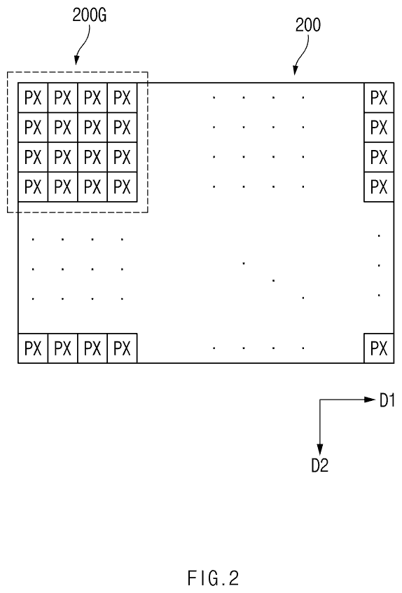

FIG. 2 is a schematic diagram illustrating an example of the pixel array 200 shown in FIG. 1 according to embodiments of the disclosed technology.

Referring to FIG. 2, the pixel array 200 may include a plurality of pixels (PXs). For example, the pixel array 200 may refer to an array having (M×N) pixels in which the pixels (PXs) are arranged in an (M×N) matrix structure (where ‘M’ is an integer of 2 or greater and ‘N’ is an integer of 2 or greater). Here, M may represent the number of pixels (PXs) arranged in a second direction (D2), and N may represent the number of pixels (PXs) arranged in a first direction (D1).

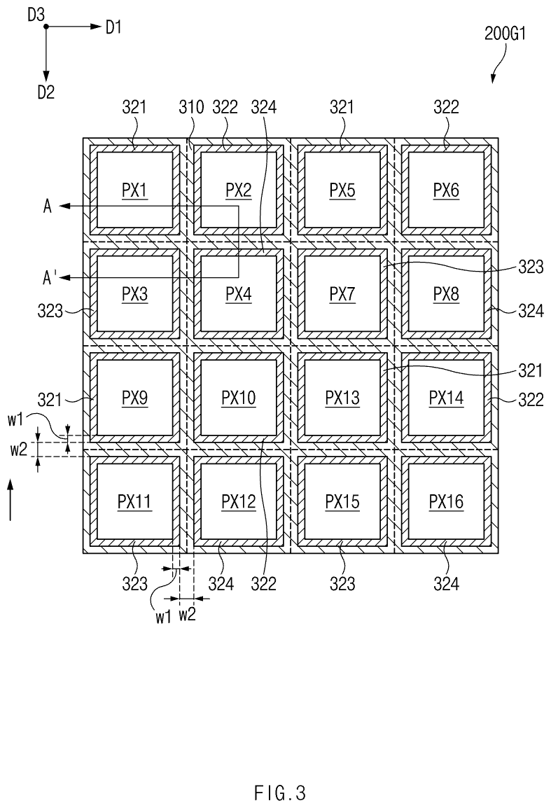

A more detailed structure of each pixel (PX) will be given below with reference to FIG. 3 and subsequent drawings using a pixel group 200G. In the example as shown in FIG. 2, 16 pixels (PXs) are arranged in a (4×4) matrix structure. The number of pixels included in the pixel group and the (4×4) matrix structure are examples only and other implementations are also possible.

FIG. 3 is a schematic diagram illustrating a first example 200G1 of the pixel group 200G shown in FIG. 2 based on some implementations of the disclosed technology.

Referring to FIG. 3, the pixel group 200G1 (hereinafter referred to as “first pixel group 200G1”) may be one example (hereinafter referred to as a first embodiment) of the pixel group 200G shown in FIG. 2. The first pixel group 200G1 may include first to sixteenth pixels (PX1˜PX16), first to fourth pixel isolation structures (321˜324) surrounding their respective pixels (PX1˜PX16), and a pixel insulation structure 310 disposed between different pixels (PX1˜PX16) and their pixel isolation structures (321˜324).

Each of the first to sixteenth pixels (PX1˜PX16) may be a minimum unit that generates an electrical signal in response to incident light. The first to sixteenth pixels (PX1˜PX16) may be arranged in a (4×4) matrix structure. For example, the first, second, fifth, and sixth pixels (PX1, PX2, PX5, PX6) may be arranged in the first direction D1. Additionally, the first, third, ninth, and eleventh pixels (PX1, PX3, PX9, PX11) may be arranged in the second direction D2. Each of the first to sixteenth pixels (PX1˜PX16) may include at least one photoelectric conversion element (not shown) and at least one optical filter (not shown). For example, the photo electric conversion element may be implemented by a photo sensing device or circuit including a photo diode, a photo transistor, a photo gate, or other photosensitive circuitry capable of converting light into a pixel signal (e.g., a charge, a voltage or a current).

Each of the first, fifth, ninth, and thirteenth pixels (PX1, PX5, PX9, PX13) may include an optical filter (not shown) configured to transmit light of a first color. Each of the first, fifth, ninth, and thirteenth pixels (PX1, PX5, PX9, PX13) may be surrounded by a first pixel isolation structure 321.

Each of the second, sixth, tenth, and fourteenth pixels (PX2, PX6, PX10, PX14) may include an optical filter (not shown) that transmits light of a second color. The second color may be different from the first color. Each of the second, sixth, tenth, and fourteenth pixels (PX2, PX6, PX10, PX14) may be surrounded by a second pixel isolation structure 322.

Each of the third, seventh, eleventh, and fifteenth pixels (PX3, PX7, PX11, PX15) may include an optical filter (not shown) configured to transmit light of a third color. The third color may be different from the first color and the second color. Each of the third, seventh, eleventh, and fifteen pixels (PX3, PX7, PX11, PX15) may be surrounded by a third pixel isolation structure 323.

Each of the fourth, eighth, twelfth, and sixteenth pixels (PX4, PX8, PX12, PX16) may include an optical filter (not shown) configured to transmit light of a fourth color. The fourth color may be different from the second color and the third color. The fourth color may be the same color as the first color, but is not limited thereto. Each of the fourth, eighth, twelfth, and sixteenth pixels (PX4, PX8, PX12, PX16) may be surrounded by a fourth pixel isolation structure 324.

In some implementations, the first color may be green, the second color may be red, the third color may be blue, and the fourth color may be green or white. In some other implementations, the first color may be magenta, the second color may be cyan, the third color may be yellow, and the fourth color may be white. The first to fourth colors as described above are examples only and other implementations are also possible.

Each of the first to fourth pixel isolation structures (321˜324) may have the same first width W1 within an error range. Each of the first to fourth pixel isolation structures (321˜324) may be formed in a square shape, but is not limited thereto. For example, the first to fourth pixel isolation structures (321˜324) may have any closed curve shapes such as a circle, a rounded square, or an octagon. The error range may refer to, for example, a range of errors that may occur in a fabrication process in which a target width of each of the first to fourth pixel isolation structures (321˜324) is set to the first width (W1).

The first to fourth pixel isolation structures (321˜324) may be spaced apart from each other. The pixel insulation structure 310 may be disposed between adjacent pixel isolation structures from among the first to fourth pixel isolation structures (321˜324). The pixel insulation structure 310 may be further disposed along the inner walls of the first to fourth pixel isolation structures (321˜324). An inner wall of any of the first to fourth pixel isolation structure (321˜324) may refer to the sidewall of the corresponding pixel isolation structure that faces the pixel surrounded by the corresponding pixel isolation structure. The pixel insulation structure 310 may be integrally formed with the first to fourth pixel isolation structures (321˜324) while surrounding each of the first to fourth pixel isolation structures (321˜324). In FIG. 3, portions of the pixel insulation structure 310 further disposed along the inner walls of the first to fourth pixel isolation structures (321˜324) are not shown in order to prevent congestion of the drawings. The pixel insulation structure 310 may have a second width W2 larger than the first width W1.

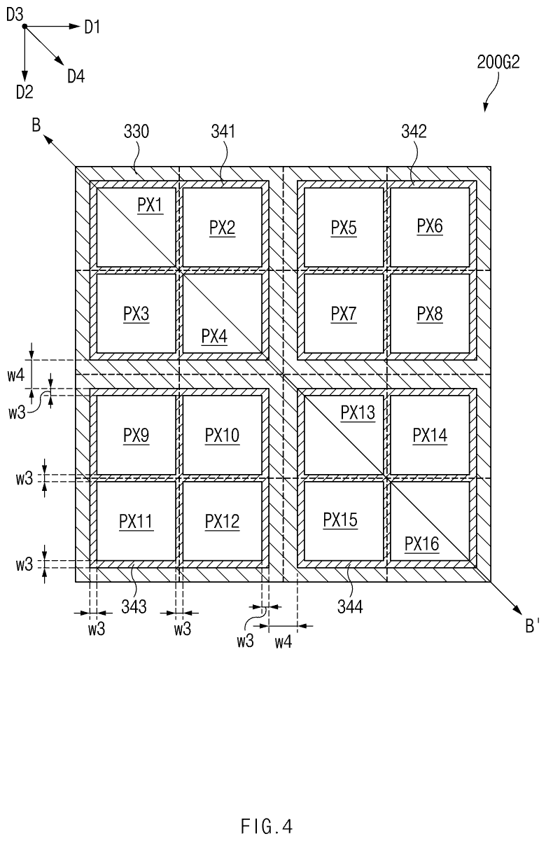

FIG. 4 is a schematic diagram illustrating a second example 200G2 of the pixel group 200G shown in FIG. 2 based on some implementations of the disclosed technology.

Hereinafter, the structure of FIG. 4 will be described centering upon differences between FIG. 3 and FIG. 4 to avoid redundant explanation.

Referring to FIG. 4, the pixel group 200G2 (hereinafter referred to as “second pixel group 200G2”) may be another example (hereinafter referred to as a second embodiment) of the pixel group 200G shown in FIG. 2. The pixel group 200G2 may include first to sixteenth pixels (PX1˜PX16), first to fourth pixel group isolation structures (341˜344), and a pixel insulation structure 330.

The first pixel group isolation structure 341 of the second pixel group 200G2 may have a structure in which the first to fourth pixel isolation structures respectively surrounding the first to fourth pixels (PX1˜PX4) are integrally formed while being in contact with each other.

The second pixel group isolation structure 342 of the second pixel group 200G2 may have a structure in which the first to fourth pixel isolation structures respectively surrounding the fifth to eighth pixels (PX5˜PX8) are integrally formed while being in contact with each other.

The third pixel group isolation structure 343 of the second pixel group 200G2 may have a structure in which the first to fourth pixel isolation structures respectively surrounding the ninth to twelfth pixels (PX9˜PX12) are integrally formed while being in contact with each other.

The fourth pixel group isolation structure 344 of the second pixel group 200G2 may have a structure in which the first to fourth pixel isolation structures respectively surrounding the thirteenth to sixteenth pixels (PX13˜PX16) are integrally formed while being in contact with each other.

While in the present implementation, the first to fourth pixel group isolation structures (341˜344) are described as the structure in which the first to fourth pixel isolation structures respectively surrounding the above four pixels are integrally formed while being in contact with each other, the number of pixel isolation structures to form the group isolation structure is not limited to four. For example, if two or more pixels are configured to have a structure in which the pixel isolation structures respectively surrounding the two or more pixels are integrally formed while being in contact with each other, such structure can be also considered as the pixel group isolation structure of the disclosed technology.

Each of the first to fourth pixels (PX1˜PX4) may include the optical filter (not shown) that transmits light of the first color. Each of the first to fourth pixels (PX1˜PX4) may be surrounded by the first pixel group isolation structure 341. The first to fourth pixels (PX1˜PX4) may be arranged in a (2×2) matrix structure. The first pixel group isolation structure 341 may be arranged in a mesh structure.

Each of the fifth to eighth pixels (PX5˜PX8) may include the optical filter (not shown) that transmits light of the second color. The second color may be different from the first color. Each of the fifth to eighth pixels (PX5˜PX8) may be surrounded by a second pixel group isolation structure 342. The fifth to eighth pixels (PX5˜PX8) may be arranged in a (2×2) matrix structure. The second pixel group isolation structure 342 may be arranged in a mesh structure.

Each of the ninth to twelfth pixels (PX9˜PX12) may include the optical filter (not shown) that transmits light of the third color. The third color may be different from the first color and the second color. Each of the ninth to twelfth pixels (PX9˜PX12) may be surrounded by the third pixel group isolation structure 343. The ninth to twelfth pixels (PX9˜PX12) may be arranged in a (2×2) matrix structure while being spaced apart from each other. The third pixel group isolation structure 343 may be arranged in a mesh structure.

Each of the thirteenth to sixteenth pixels (PX13˜PX16) may include the optical filter (not shown) that transmits light of the fourth color. The fourth color may be different from the second color and the third color. The fourth color may be the same color as the first color, but is not limited thereto. Each of the thirteenth to sixteenth pixels (PX13˜PX16) may be surrounded by the fourth pixel group isolation structure 344. Each of the thirteenth to sixteenth pixels (PX13˜PX16) may be arranged in a (2×2) matrix structure while being spaced apart from each other. The fourth pixel group isolation structure 344 may be arranged in a mesh structure.

In some implementations, the first color may be green, the second color may be red, the third color may be blue, and the fourth color may be green or white. In some other implementations, the first color may be magenta, the second color may be cyan, the third color may be yellow, and the fourth color may be white. The first to fourth colors as described above are examples only and other implementations are also possible.

Each of the first to fourth pixel group isolation structures (341˜344) may have the same third width W3 within the error range. Each of the first to fourth pixel group isolation structures (341˜344) may be formed in a square mesh structure, but is not limited thereto. For example, the first to fourth pixel group isolation structures (341˜344) may have any one of closed curve-shaped mesh structures such as a circle, a rounded square, or an octagon.

The error range may refer to, for example, a range of errors that may occur in a fabrication process in which a target width of each of the first to fourth pixel group isolation structures (341˜344) is set to the third width (W3).

The first to fourth pixel group isolation structures (341˜344) may be spaced apart from each other. The pixel insulation structure 330 may be disposed in a space between the first to fourth pixel group isolation structures (341˜344) that are spaced apart from each other. The pixel insulation structure 330 may be further disposed along the inner walls of the first to fourth pixel group isolation structures (341˜344). An inner wall of any one of the first to fourth pixel group isolation structure (341˜344) may refer to the sidewall of the pixel group isolation structure that faces the pixel surrounded by the pixel group isolation structure. The pixel insulation structure 330 may be formed integrally with each of the first to fourth pixel group isolation structures (341˜344) while surrounding each of the first to fourth pixel group isolation structures (341˜344). In FIG. 3, portions of the pixel insulation structure 330 further disposed along the inner walls of the first to fourth pixel group isolation structures (341˜344) are not shown in order to prevent congestion of the drawings. The pixel insulation structure 330 may have a fourth width W4 larger than the third width W3.

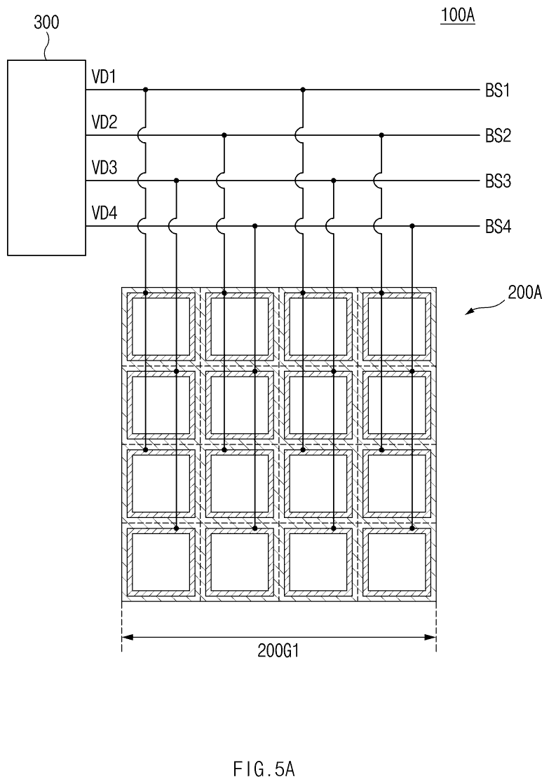

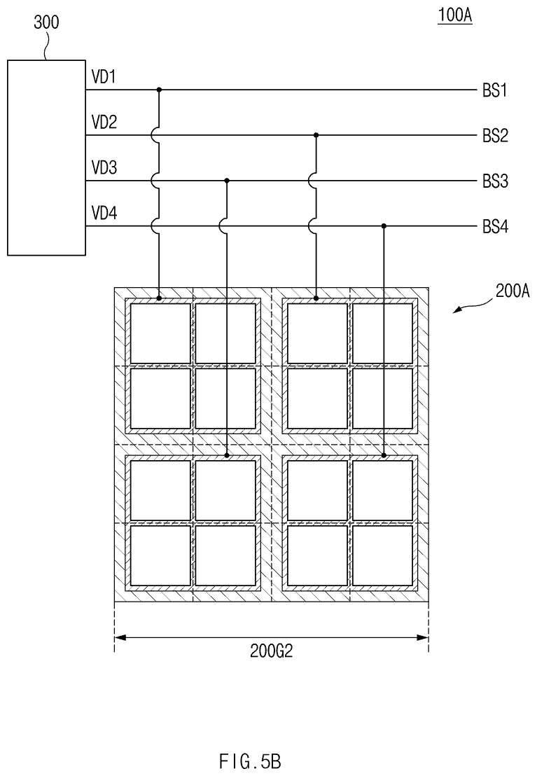

FIG. 5A is a schematic diagram illustrating an example in which a bias voltage is applied to a first pixel group shown in FIG. 3 according to embodiments of the disclosed technology.

FIG. 5B is a schematic diagram illustrating an example in which a bias voltage is applied to a second pixel group shown in FIG. 4 according to embodiments of the disclosed technology.

Referring to FIGS. 3, 4, 5A, and 5B, the image sensing device 100A may be a portion of the image sensing device 100 shown in FIG. 1. The image sensing device 100A may include a bias voltage generator 300 and a portion 200A of the pixel array.

In order to avoid complexity of the drawings, the reference numerals of the constituent elements of the first pixel group 200G1 of FIG. 3 and the reference numerals of the constituent elements of the second pixel group 200G2 of FIG. 4 will herein be omitted from FIGS. 5A and 5B.

The bias voltage generator 300 may control a plurality of bias signals that control bias voltages to be applied to the pixel isolation structures. In some implementations, the bias voltage generator 300 may generate first to fourth bias signals (BS1˜BS4). In some other implementations, the bias voltage generator 300 may receive the first to fourth bias signals (BS1˜BS4) from the timing generator (110 of FIG. 1). Hereinafter, an exemplary embodiment in which the bias voltage generator 300 generates the first to fourth bias signals (BS1˜BS4) will be described as an example with reference to the attached drawings.

Referring to FIGS. 3 and 5A, the bias voltage generator 300 may generate a first bias signal BS1 that controls a first bias voltage VD1 to be applied to the first pixel isolation structures 321. The bias voltage generator 300 may generate a second bias signal BS2 that controls a second bias voltage VD2 to be applied to the second pixel isolation structures 322. The bias voltage generator 300 may generate a third bias signal BS3 that controls a third bias voltage VD3 to be applied to the third pixel isolation structures 323. The bias voltage generator 300 may generate a fourth bias signal BS4 that controls the fourth bias voltage VD4 to be applied to the fourth pixel isolation structures 324.

Referring to FIGS. 4 and 5B, the bias voltage generator 300 may generate a first bias signal BS1 that controls a first bias voltage VD1 to be applied to a first pixel group isolation structure 341. The bias voltage generator 300 may generate a second bias signal BS2 that controls a second bias voltage VD2 to be applied to a second pixel group isolation structure 342. The bias voltage generator 300 may generate a third bias signal BS3 that controls a third bias voltage VD3 to be applied to the third pixel group isolation structures 343. The bias voltage generator 300 may generate a fourth bias signal BS4 that controls a fourth bias voltage VD4 to be applied to the fourth pixel group isolation structures 344.

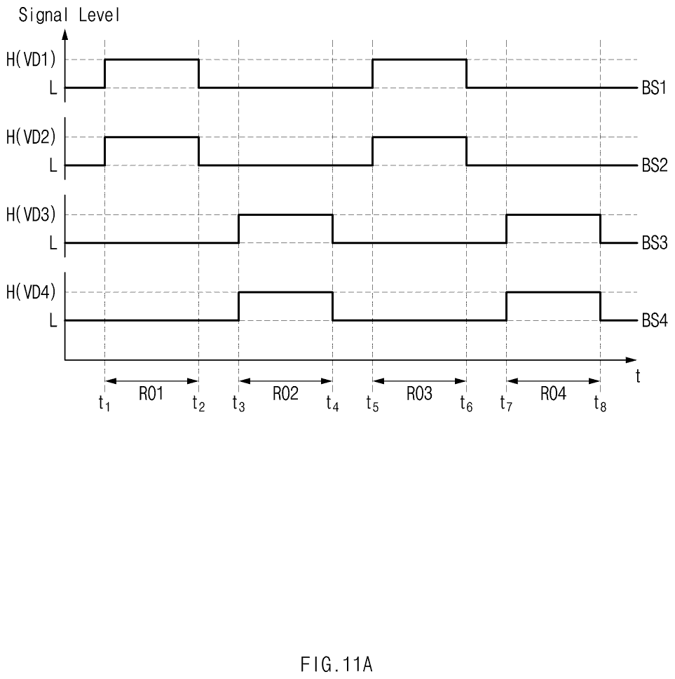

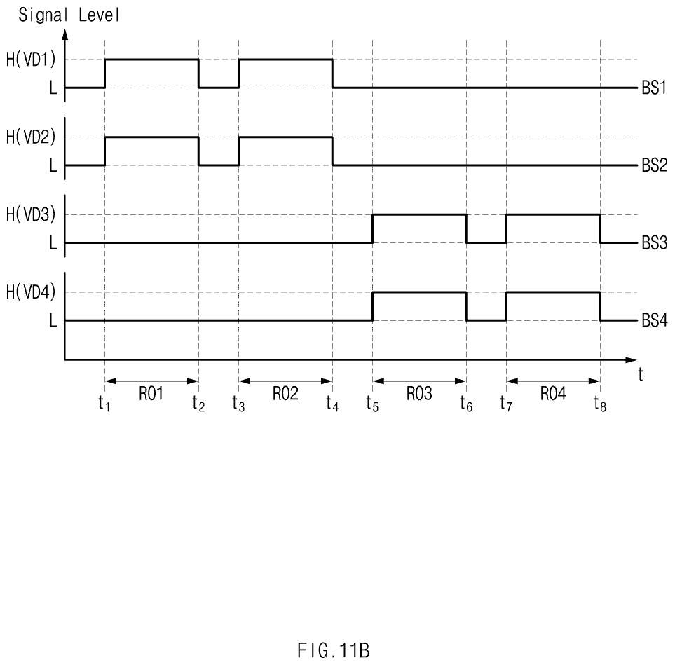

The magnitudes of the first to fourth bias voltages (VD1˜VD4) may have values determined experimentally as described with reference to FIG. 1. The magnitude relationship between the first to fourth bias voltages (VD1˜VD4) will be described later in this patent document with reference to FIG. 11A.

Although FIGS. 5A and 5B illustrate that a portion 200A of the pixel array includes the first pixel group 200G1 or the second pixel group 200G2, other implementations are also possible. For example, the pixel array (200 of FIG. 2) may include both the first pixel group 200G1 and the second pixel group 200G2 as necessary.

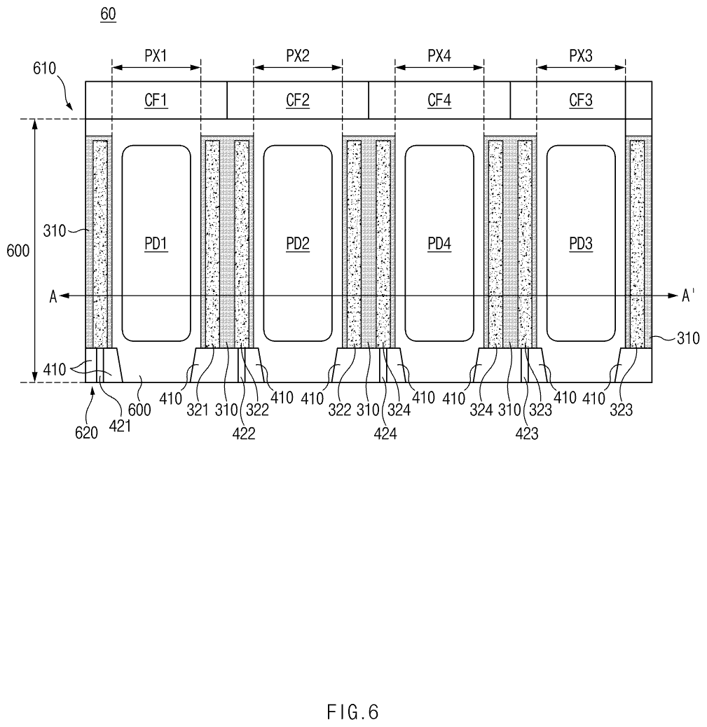

FIG. 6 is a cross-sectional view illustrating an example of the pixel group taken along the line A-A′ of FIG. 3 according to embodiments of the disclosed technology.

Referring to FIGS. 3 and 6, a first cross-section 60 may include first to fourth optical filters (CF1˜CF4), a semiconductor substrate 600, a pixel insulation structure 310, first to fourth pixel isolation structures (321˜324), an insulation trench structure 410, first to fourth photoelectric conversion elements or photodetectors (PD1˜PD4), and first to fourth bias contacts (421˜424).

The semiconductor substrate 600 may be formed of or include a silicon-based material (e.g., silicon (Si), silicon germanium (SiGe), etc.). The semiconductor substrate 600 may include a first surface 610 and a second surface 620 facing or opposite to the first surface 610. The first surface 610 may be, for example, a back surface (or a back side) upon which light is incident. The second surface 620 may be, for example, a front surface (or a front side) of the semiconductor substrate.

A first optical filter or color filter CF1 may overlap, or be included as part of, the first pixel PX1 and may be disposed over the first surface 610 of the semiconductor substrate 600. The first optical filter CF1 may overlap a first photoelectric conversion element or photodetector PD1. The first optical filter CF1 may selectively transmit light of the first color from among incident light. The first color light may be, for example, green light. The green light may refer to light having a wavelength of a preset range (e.g., 500 nm to 600 nm).

A second optical filter or color filter CF2 may overlap, or be included as part of, the second pixel PX2 and may be disposed over the first surface 610 of the semiconductor substrate 600. The second optical filter CF2 may overlap a second photoelectric conversion element or photodetector PD2. The second optical filter CF2 may selectively transmit light of the second color from among incident light. The second color light may be, for example, red light. The red light may refer to light having a wavelength of a preset range (e.g., 600 nm to 700 nm).

A third optical filter or color filter CF3 may overlap, or be included as part of, the third pixel PX3 and may be disposed over the first surface 610 of the semiconductor substrate 600. The third optical filter CF3 may overlap a third photoelectric conversion element or photodetector PD3. The third optical filter CF3 may selectively transmit light of the third color from among incident light. The third color light may be, for example, blue light. The blue light may refer to light having a wavelength of a preset range (e.g., 400 nm to 500 nm).

A fourth optical filter or color filter CF4 may overlap, or be included as part of, the fourth pixel PX4 and may be disposed over the first surface 610 of the semiconductor substrate 600. The fourth optical filter CF4 may overlap a fourth photoelectric conversion element or photodetector PD4. The fourth optical filter CF4 may selectively transmit light of the first color or light of the fourth color from among incident light. The fourth color light may be, for example, white light. The white light may refer to light having a wavelength of a preset range (e.g., 400 nm to 700 nm).

In the first pixel PX1, the first photoelectric conversion element or photodetector PD1 may generate photocharges in response to incident light. The incident light may be light of a first color that has passed through the first optical filter CF1. The first photoelectric conversion element or photodetector PD1 may be disposed within the semiconductor substrate 600. The first photoelectric conversion element or photodetector PD1 may overlap the first optical filter CF1.

In the second pixel PX2, the second photoelectric conversion element or photodetector PD2 may generate photocharges in response to incident light. The incident light may be light of a second color that has passed through the second optical filter CF2.

The second photoelectric conversion element PD2 may be disposed within the semiconductor substrate 600. The second photoelectric conversion element PD2 may overlap the second optical filter CF2.

In the third pixel PX3, the third photoelectric conversion element or photodetector PD3 may generate photocharges in response to incident light. The incident light may be light of a third color that has passed through the third optical filter CF3. The third photoelectric conversion element PD3 may be disposed within the semiconductor substrate 600. The third photoelectric conversion element PD3 may overlap the third optical filter CF3.

In the fourth pixel PX4, the fourth photoelectric conversion element or photodetector PD4 may generate photocharges in response to incident light. The incident light may be light of a fourth color that has passed through the fourth optical filter CF4. The fourth photoelectric conversion element PD4 may be disposed within the semiconductor substrate 600. The fourth photoelectric conversion element PD4 may overlap the fourth optical filter CF4.

In some implementations, the first pixel isolation structure 321 may be recessed from the insulation trench structure 410 into the semiconductor substrate 600 in one direction. In some other implementations, the first pixel isolation structure 321 may be recessed from the second surface 620 of the semiconductor substrate 600 into the semiconductor substrate 600. The pixel group 200G1 may have one of the above two examples depending on a sequence of fabrication processes. For example, when forming the insulation trench structure 410 after forming the first pixel isolation structure 321, the first pixel isolation structure 321 may be recessed in one direction from the insulation trench structure 410 into the semiconductor substrate 600 as shown in FIG. 6. In another example, when forming the first pixel isolation structure 321 after forming the insulation trench structure 410 first, the first pixel isolation structure 321 may penetrate the insulation trench structure 410 and may be recessed from the second surface 620 into the semiconductor substrate 600, unlike shown in FIG. 6. In some other implementations, the first pixel isolation structure 321 may be recessed from the first surface 610 into the semiconductor substrate 600 in the other direction opposite to the one direction. In the description below, for convenience of description, one embodiment in which the first to fourth pixel isolation structures (321˜324) are recessed from the insulation trench structure 410 that may be formed on the second surface 620 into the semiconductor substrate 600 will hereinafter be described as an example with reference to the attached drawings.

The first pixel isolation structure 321 may include, for example, any one of polysilicon, polysilicon containing impurities, or a combination thereof. The first pixel isolation structure 321 may surround the first photoelectric conversion element PD1.

The second pixel isolation structure 322 may be recessed from the insulation trench structure 410 into the semiconductor substrate 600 in one direction. The second pixel isolation structure 322 may include, for example, any one of polysilicon, polysilicon containing impurities, or a combination thereof. The second pixel isolation structure 322 may surround the second photoelectric conversion element PD2.

The third pixel isolation structure 323 may be recessed from the insulation trench structure 410 into the semiconductor substrate 600 in one direction. The third pixel isolation structure 323 may include, for example, any one of polysilicon, polysilicon containing impurities, or a combination thereof. The third pixel isolation structure 323 may surround the third photoelectric conversion element PD3.

The fourth pixel isolation structure 324 may be recessed from the insulation trench structure 410 into the semiconductor substrate 600 in one direction. The fourth pixel isolation structure 324 may include, for example, any one of polysilicon, polysilicon containing impurities, or a combination thereof. The fourth pixel isolation structure 324 may surround the fourth photoelectric conversion element PD4.

The first to fourth pixel isolation structures (321˜324) may optically isolate adjacent pixels (e.g., prevent crosstalk). For example, the first pixel isolation structure 321 or the second pixel isolation structure 322 may prevent crosstalk between the first pixel PX1 and the second pixel PX2. Additionally, the first to fourth pixel isolation structures (321˜324) may reduce noise of the first to fourth pixels (PX1˜PX4) upon receiving a bias voltage through the first to fourth bias contacts (421˜424).

The pixel insulation structure 310 may surround each of the first to fourth pixel isolation structures (321˜324). The pixel insulation structure 310 may include an insulation material (e.g., silicon dioxide, silicon nitrogen, a silicon oxide-based insulation material, or a silicon nitride-based insulation material). The pixel insulation structure 310 may be recessed from the insulation trench structure 410 in the one direction in which the first to fourth pixel isolation structures (321˜324) are recessed, into the semiconductor substrate 600. The pixel insulation structure 310 may further gap-fill each of the spaces between the first to fourth pixel isolation structures (321˜324), or may be further disposed in the space between the first to fourth pixel isolation structures (321˜324).

For example, a trench (e.g., a first trench (i.e., a trench for forming the pixel insulation structure 310)) recessed from the second surface 620 into the semiconductor substrate 600 may be formed, and the first trench may be gap-filled with the insulation material, resulting in formation of the pixel insulation structure 310. Two trenches (e.g., a second trench (i.e., a trench for forming the first pixel isolation structure 321) and a third trench (i.e., a trench for forming the second pixel isolation structure 322)) that penetrate the pixel insulation structure 310 while being spaced apart from each other may be formed. Each of the second trench and the third trench may be gap-filled with polysilicon or doped polysilicon, resulting in formation of the first pixel isolation structure 321 and the second pixel isolation structure 322. Then, a trench (e.g., a fourth trench (i.e., a trench for forming an insulation trench structure 410)) for removing a portion of the pixel insulation structure 310, a portion of the first and second pixel isolation structures (321, 322) may be formed to be recessed from the second surface 620. For example, the fourth trench may be gap-filled with the same material as the pixel insulation structure 310, resulting in formation of an insulation trench structure 410.

The pixel insulation structure 310 may electrically isolate (or insulate) the first to fourth pixel isolation structures (321˜324) from each other. Due to such electrical isolation (or insulation), a bias voltage may be applied independently to each of the first to fourth pixel isolation structures (321˜324).

The insulation trench structure 410 may have a structure that is recessed in one direction from the second surface 620 (alternatively, from the first surface 610 according to another embodiment) into the semiconductor substrate 600. The insulation trench structure 410 may be recessed to have a smaller depth than the first to fourth pixel isolation structures (321˜324). The insulation trench structure 410 may include the same material as the pixel insulation structure 310. The insulation trench structure 410 may electrically isolate adjacent pixels from each other. For example, the insulation trench structure 410 may electrically isolate the first pixel PX1 and the second pixel PX2 from each other. Although not shown in the vicinity of the second surface 620, one or more floating diffusion regions capable of accumulating photocharges generated by the first to fourth photoelectric conversion elements (PD1˜PD4) or transfer transistors capable of moving such photocharges from each of the photoelectric conversion elements toward each of the floating diffusion regions can be disposed in the vicinity of the second surface 620. The insulation trench structure 410 may prevent electrical interaction between the transfer transistors of the adjacent pixels or between the floating diffusion regions of the adjacent pixels.

A first bias contact 421 may have a structure that is recessed in one direction from the second surface 620 (alternatively, from the first surface 610 according to another embodiment) into the semiconductor substrate 600. The first bias contact 421 may be in contact with the first pixel isolation structure 321 by penetrating the insulation trench structure 410. The first bias contact 421 may apply a first bias voltage to the first pixel isolation structure 321. The reason why the first bias contact 421 contacts only the first pixel isolation structure 321 located at the left side of FIG. 6 is that the first pixel isolation structure 321 located at the left side of FIG. 6 and the first pixel isolation structure 321 located at the right side of FIG. 6 are connected to each other (see FIG. 3).

A second bias contact 422 may have a structure that is recessed in one direction from the second surface 620 (alternatively, from the first surface 610 according to another embodiment) into the semiconductor substrate 600. The second bias contact 422 may be in contact with the second pixel isolation structure 322 by penetrating the insulation trench structure 410. The second bias contact 422 may apply a second bias voltage to the second pixel isolation structure 322. The reason why the second bias contact 422 contacts only the second pixel isolation structure 322 located at the left side of FIG. 6 is that the second pixel isolation structure 322 located at the left side of FIG. 6 and the second pixel isolation structure 322 located at the right side of FIG. 6 are connected to each other (see FIG. 3).

A third bias contact 423 may have a structure that is recessed in one direction from the second surface 620 (alternatively, from the first surface 610 according to another embodiment) into the semiconductor substrate 600. The third bias contact 423 may be in contact with the third pixel isolation structure 323 by penetrating the insulation trench structure 410. The third bias contact 423 may apply a third bias voltage to the third pixel isolation structure 323. The reason why the third bias contact 423 contacts only the third pixel isolation structure 323 located at the left side of FIG. 6 is that the third pixel isolation structure 323 located at the left side of FIG. 6 and the third pixel isolation structure 323 located at the right side of FIG. 6 are connected to each other (see FIG. 3).

A fourth bias contact 424 may have a structure that is recessed in one direction from the second surface 620 (alternatively, from the first surface 610 according to another embodiment) into the semiconductor substrate 600. The fourth bias contact 424 may be in contact with the fourth pixel isolation structure 324 by penetrating the insulation trench structure 410. The fourth bias contact 424 may apply a fourth bias voltage to the fourth pixel isolation structure 324. The reason why the fourth bias contact 424 contacts only the fourth pixel isolation structure 324 located at the left side of FIG. 6 is that the fourth pixel isolation structure 324 located at the left side of FIG. 6 and the fourth pixel isolation structure 324 located at the right side of FIG. 6 are connected to each other (see FIG. 3).

The first to fourth bias contacts (421˜424) may be formed of or include a metal material (e.g., copper (Cu), tungsten (W), etc.). When the first to fourth bias voltages are applied to the first to fourth pixel isolation structures (321˜324) through the first to fourth bias contacts (421˜424), respectively, the amount of noise (including, e.g., the amount of dark current) of each of the first to fourth pixels (PX1˜PX4) may be reduced.

A phenomenon that occurs when a bias voltage is applied to the pixel isolation structure is described below as a representative example with respect to the first pixel isolation structure 321 for the first pixel PX1. Referring to FIG. 6 and FIG. 3, when a negative bias voltage is applied to a pixel, e.g., the first pixel isolation structure 321 surrounding the first pixel PX1, for example, electrons in the first pixel isolation structure 321 may move along the direction of the local electrical field caused by the negative bias voltage to a position close to the sidewall of the first pixel isolation structure 321. Such movement of the electrons in the first pixel isolation structure 321 effectuates holes in the semiconductor substrate 600 of the first pixel PX1 to move towards an area close to the first pixel isolation structure 321 (e.g., an interface between the pixel insulation structure 310 disposed between different pixels (PX1˜PX16) and their pixel isolation structures (321˜324) and first pixel isolation structure 321 surrounding the first pixel (PX1)). As such, holes in the semiconductor substrate 600 of the first pixel PX1 may be accumulated and fixed at the interface between the pixel insulation structure 310 and first pixel isolation structure 321, thereby decreasing the dark current of the semiconductor substrate 600 and decreasing the noise at the first pixel PX1. As the intensity of the bias voltage applied to the first pixel isolation structure 321 changes, the amount of holes accumulated and fixed at the interface of the pixel insulation structure 310 increases, thereby further reducing noise at the first pixel PX1. In the example, the bias voltage is applied to the first pixel isolation structure 321 through the first bias contact 421.

FIG. 6 is a cross-sectional view illustrating an example of the pixel group taken along the line A-A′ of FIG. 3 according to embodiments of the disclosed technology.

FIG. 6 illustrates an example in which the first to fourth bias contacts (421˜424) are located on the line A-A′ of FIG. 3 for convenience of explanation, but other implementations are also possible. For example, the first to fourth bias contacts (421˜424) may be disposed on different locations without being limited to being on the line A-A′ of FIG. 3.

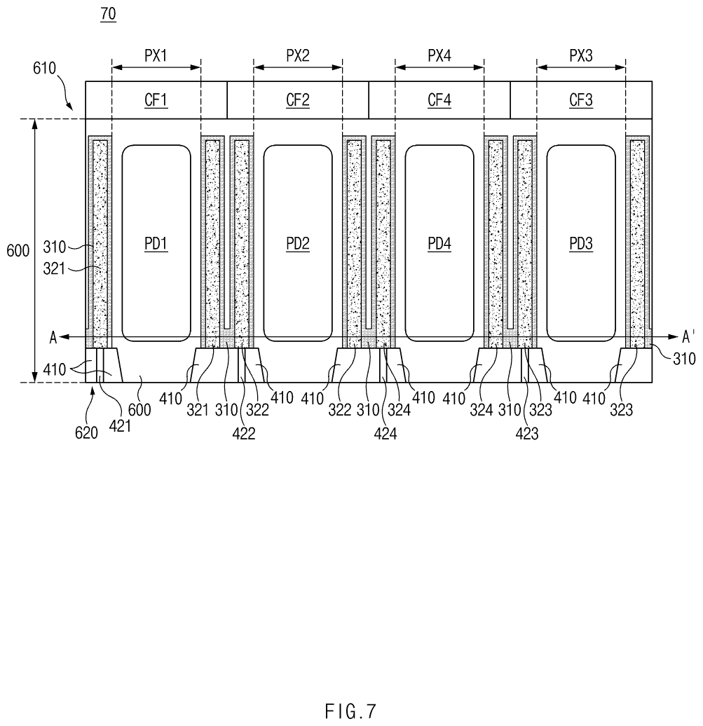

FIG. 7 is a cross-sectional view illustrating another example of the pixel group taken along the line A-A′ of FIG. 3 according to embodiments of the disclosed technology.

Referring to FIGS. 3, 6, and 7, a second cross-section 70 may include first to fourth optical filters (CF1˜CF4), a semiconductor substrate 600, a pixel insulation structure 310, first to fourth pixel isolation structures (321˜324), an insulation trench structure 410, first to fourth photoelectric conversion elements or photodetectors (PD1˜PD4), and first to fourth bias contacts (421˜424).

Hereinafter, the structure of FIG. 7 will be described centering upon differences between FIG. 6 and FIG. 7 to avoid redundant explanation.

The pixel insulation structure 310 may surround each of the first to fourth pixel isolation structures (321˜324). For pixel isolation structures adjacent to each other among the first to fourth pixel isolation structures (321˜324), when the two adjacent pixel isolation structures are spaced apart from each other such that the adjacent pixel isolation structures are electrically isolated from each other, the pixel insulation structure 310 does not gap-fill the spaces between the first to fourth pixel isolation structures (321˜324), but may be configured such that a recess depth where the pixel insulation structure 310 is recessed from the second surface 620 (or the first surface 610 according to another embodiment) into the semiconductor substrate 600 is smaller than a recess depth where the first to fourth pixel isolation structures (321˜324) are recessed into the semiconductor substrate 600, and is also greater than a recess depth where the insulation trench structure 410 is recessed into the semiconductor substrate 600.

For example, two trenches (e.g., first and second trenches) recessed from the second surface 620 into the semiconductor substrate 600 may be formed. After removing the area between the first and second trenches to a depth smaller than those of the two trenches, a layer including the insulation material may be formed in a region (e.g., an etched region) from which the semiconductor substrate 600 has been removed, resulting in formation of the pixel insulation structure 310. After the pixel insulation structure 310 is formed, the first and second trench regions may be gap-filled to form the first pixel isolation structure 321 and the second pixel isolation structure 322. Then, a trench (e.g., a third trench) formed when the first and second pixel isolation structures (321, 322) and the pixel insulation structure 310 are partially removed may be formed to be recessed from the second surface 620. For example, the third trench may be gap-filled with the same material as the pixel insulation structure 310, resulting in formation of the insulation trench structure 410.

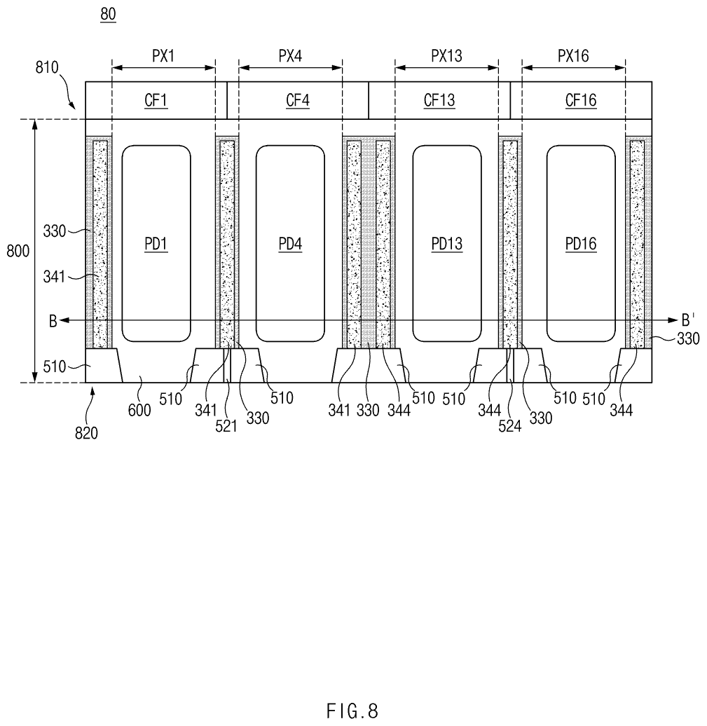

FIG. 8 is a cross-sectional view illustrating an example of the pixel group taken along the line B-B′ of FIG. 4 according to embodiments of the disclosed technology.

Referring to FIGS. 4 and 8, the third cross-section 80 may include first, fourth, thirteenth, and sixteenth optical filters (CF1, CF4, CF13, CF16), a semiconductor substrate 800, a pixel insulation structure 330, first and fourth pixel group isolation structures (341, 344), an insulation trench structure 510, first, fourth, thirteenth, and sixteenth photoelectric conversion elements (PD1, PD4, PD13, PD16), and first and fourth group bias contacts (521, 524).

Hereinafter, descriptions overlapping with those of FIG. 6 will be omitted or simply given for convenience of description. The semiconductor substrate 800 may be substantially the same as the semiconductor substrate 600 of FIG. 6. The first optical filter CF1 may be substantially the same as the first optical filter CF1 shown in FIG. 6. The first and fourth photoelectric conversion elements (PD1, PD4) shown in FIG. 8 may be substantially the same as the first and fourth photoelectric conversion elements (PD1, PD4) shown in FIG. 6. The insulation trench structure 510 shown in FIG. 8 may be substantially the same as the insulation trench structure 410 of FIG. 6.

The fourth optical filter CF4 may overlap the fourth pixel PX4 and may be disposed over the first surface 810 of the semiconductor substrate 800. The fourth optical filter CF4 may overlap the fourth photoelectric conversion element PD4. The fourth optical filter CF4 may selectively transmit light of the first color described in FIG. 6 from among the incident light.

The thirteenth optical filter CF13 may overlap the thirteenth pixel PX13 and may be disposed over the first surface 810 of the semiconductor substrate 800. The thirteenth optical filter CF13 may overlap the thirteenth photoelectric conversion element PD13. The thirteenth optical filter CF13 may also selectively transmit light of the fourth color or light of the first color described in FIG. 6 from among incident light.

The sixteenth optical filter CF16 may overlap the sixteenth pixel PX16 and may be disposed over the first surface 810 of the semiconductor substrate 800. The sixteenth optical filter CF16 may overlap the sixteenth photoelectric conversion element PD16. The sixteenth optical filter CF16 may also selectively transmit light of the fourth color or light of the first color described in FIG. 6 from among incident light.

The fourth photoelectric conversion element PD4 may generate photocharges in response to incident light. The incident light may be light of the first color that has penetrated the fourth optical filter CF4.

The thirteenth photoelectric conversion element PD13 may generate photocharges in response to incident light. The incident light may be light of the first color or light of the fourth color that has penetrated the thirteenth optical filter CF13. The thirteenth photoelectric conversion element PD13 may be disposed in the semiconductor substrate 800. The thirteenth photoelectric conversion element PD13 may overlap the thirteenth optical filter CF13.

The sixteenth photoelectric conversion element PD16 may generate photocharges in response to incident light. The incident light may be light of the first color or light of the fourth color that has penetrated the sixteenth optical filter CF16. The sixteenth photoelectric conversion element PD16 may be disposed in the semiconductor substrate 800. The sixteenth photoelectric conversion element PD16 may overlap the sixteenth optical filter CF16.

In some implementations, the first pixel group isolation structure 341 may be recessed in one direction from the insulation trench structure 510 into the semiconductor substrate 800. In some other implementations, the first pixel group isolation structure 341 may be recessed in one direction from the second surface 820 of the semiconductor substrate 800 into the semiconductor substrate 800. The above two examples may vary depending on a sequence of fabrication processes. For example, when forming the insulation trench structure 510 after forming the first pixel group isolation structure 341, the first pixel group isolation structure 341 may be recessed in one direction from the insulation trench structure 510 into the semiconductor substrate 800 as shown in FIG. 8. However, when forming the first pixel group isolation structure 341 after forming the insulation trench structure 510 first, the first pixel group isolation structure 341 may penetrate the insulation trench structure 510 and may be recessed from the second surface 820 into the semiconductor substrate 800, unlike shown in FIG. 8. Additionally, according to another embodiment, the first pixel group isolation structure 341 may be recessed from the first surface 810 into the semiconductor substrate 800 in the direction opposite to the one direction. However, for convenience of description, one embodiment in which the first to fourth pixel group isolation structures (e.g., 341, 342, 343 and 344 of FIG. 4) are recessed from the insulation trench structure 510 that may be formed on the second surface 820 into the semiconductor substrate 800 will hereinafter be described as an example with reference to the attached drawings.

For example, the first pixel group isolation structure 341 may be recessed in one direction from the insulation trench structure 510 into the semiconductor substrate 800. The first pixel group isolation structure 341 may include, for example, any one of polysilicon, polysilicon containing impurities, or a combination thereof. The first pixel group isolation structure 341 may surround the first photoelectric conversion element PD1 and the fourth photoelectric conversion element PD4. Referring back to FIG. 4, the first pixel group isolation structure 341 may surround the first to fourth photoelectric conversion elements (PD1˜PD4).

For example, the fourth pixel group isolation structure 344 may be recessed in one direction from the insulation trench structure 510 into the semiconductor substrate 800. The fourth pixel group isolation structure 344 may include, for example, any one of polysilicon, polysilicon containing impurities, or a combination thereof. The fourth pixel group isolation structure 344 may surround the thirteenth photoelectric conversion element PD13 and the sixteenth photoelectric conversion element PD16. Referring back to FIG. 4, the fourth pixel group isolation structure 344 may surround the thirteenth to sixteenth photoelectric conversion elements (PD13˜PD16).

The first pixel group isolation structure 341 may optically isolate the first to fourth pixels (PX1˜PX4) from each other. As an example, the first pixel group isolation structure 341 may optically isolate the first pixel PX1 and the fourth pixel PX4 from each other. Additionally, when a bias voltage is applied to the first pixel group isolation structure 341 through the first group bias contact 521, noise in the first to fourth pixels (PX1˜PX4) can be reduced.

The fourth pixel group isolation structure 344 may optically isolate the thirteenth to sixteenth pixels (PX13˜PX16) from each other. As an example, the fourth pixel group isolation structure 344 may optically isolate the thirteenth pixel PX13 and the sixteenth pixel PX16 from each other. Additionally, when a bias voltage is applied to the fourth pixel group isolation structure 344 through the fourth group bias contact 524, noise in the thirteenth to sixteenth pixels (PX13˜PX16) can be reduced.

A first group bias contact 521 may have a structure that is recessed in one direction from the second surface 820 (alternatively, from the first surface 810 according to another embodiment) into the semiconductor substrate 800. The first group bias contact 521 may be in contact with the first pixel group isolation structure 341 by penetrating the insulation trench structure 510. The first group bias contact 521 may apply a first bias voltage to the first pixel group isolation structure 341. The reason why the first group bias contact 521 is shown to contact only the central first pixel group isolation structure 341 from among three first pixel group isolation structures 341 of FIG. 8 is that the three first pixel group isolation structures 341 are connected to each other and formed integrally (see FIG. 4).

A fourth group bias contact 524 may have a structure that is recessed in one direction from the second surface 820 (alternatively, from the first surface 810 according to another embodiment) into the semiconductor substrate 800. The fourth group bias contact 524 may be in contact with the fourth pixel group insulation structure 344 by penetrating the insulation trench structure 510. The fourth group bias contact 524 may apply a fourth bias voltage to the fourth pixel group isolation structure 344. The reason why the fourth group bias contact 524 is shown to contact only the central fourth pixel group isolation structure 344 from among three fourth pixel group isolation structures 344 is that the three fourth pixel group isolation structures 344 are connected to each other and formed integrally (see FIG. 4).

The pixel insulation structure 330 may surround each of the first and fourth pixel group isolation structures (341, 344). The pixel insulation structure 330 may include an insulation material (e.g., silicon dioxide, silicon nitrogen, a silicon oxide-based insulation material, or a silicon nitride-based insulation material). The pixel insulation structure 330 may be recessed from the insulation trench structure 510 in the one direction in which the first and fourth pixel group isolation structures (341, 344) are recessed, into the semiconductor substrate 800. The pixel insulation structure 330 may further gap-fill the space between the first and fourth pixel group isolation structures (341, 344), or may be further disposed in a region corresponding to the space between the first and fourth pixel group isolation structures (341, 344).

For example, a trench (e.g., a first trench) recessed from the second surface 820 into the semiconductor substrate 800 may be formed, and the first trench may be gap- filled with the insulation material, resulting in formation of a pixel insulation structure 330. Two trenches (e.g., the second trench and the third trench) spaced apart from each other while penetrating the pixel insulation structure 330 may be formed, and each of the second trench and the third trench may be gap-filled with polysilicon or doped polysilicon, so that the first pixel group isolation structure 341 and the fourth pixel group isolation structure 344 can be formed. Thereafter, a trench (e.g., a fourth trench) for removing a portion of the first and fourth pixel group isolation structures (341, 344) may be formed to be recessed from the second surface 820. For example, the fourth trench may be gap-filled with the same material as the pixel insulation structure 330, resulting in formation of an insulation trench structure 510.

The pixel insulation structure 330 may electrically isolate (or insulate) the first and fourth pixel group isolation structures 341 and 344 from each other. Due to such electrical isolation (or insulation), a bias voltage may be applied independently to each of the first and fourth pixel group isolation structures (341, 344). Furthermore, referring back to FIG. 4, due to the insulation function (i.e., the electrical isolation or insulation) of the pixel insulation structure 330, a bias voltage may be applied independently to each of the first to fourth pixel group isolation structures (341˜344).

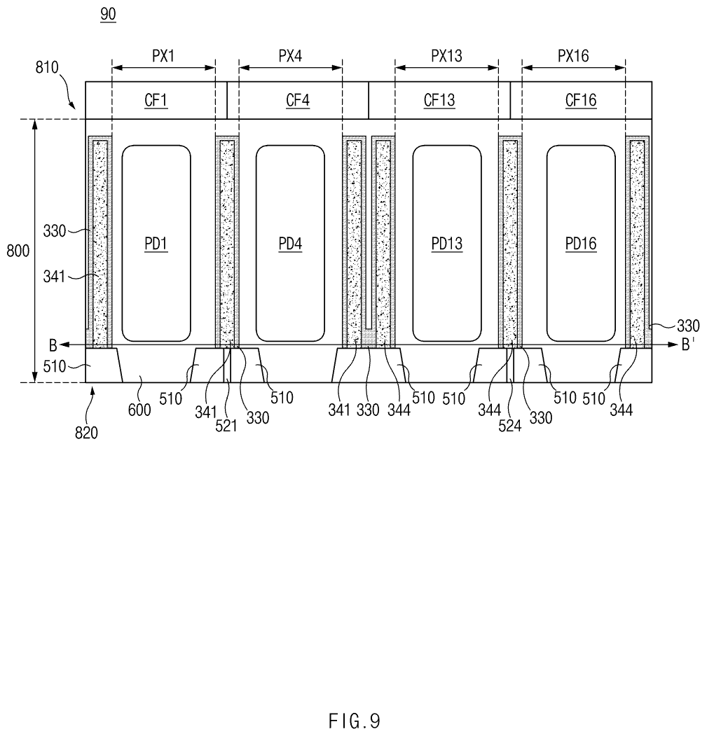

FIG. 9 is a cross-sectional view illustrating another example of the pixel group taken along the line B-B′ of FIG. 4 according to embodiments of the disclosed technology.

Referring to FIGS. 4, 8 and 9, the fourth cross-section 90 may include first, fourth, thirteenth, and sixteenth optical filters (CF1, CF4, CF13, CF16), a semiconductor substrate 800, a pixel insulation structure 330, first and fourth pixel group isolation structures (341, 344), an insulation trench structure 510, first, fourth, thirteenth, and sixteenth photoelectric conversion elements (PD1, PD4, PD13, PD16), and first and fourth group bias contacts (521, 524).

Hereinafter, the structure of FIG. 9 will be described centering upon differences between FIG. 8 and FIG. 9 to avoid redundant explanation.

The pixel insulation structure 330 may surround each of the first and fourth pixel group isolation structures (341, 344). For pixel group isolation structures adjacent to each other among the first and fourth pixel group isolation structures (341, 344), when the two adjacent pixel group isolation structures are spaced apart from each other such that the adjacent pixel group isolation structures are electrically isolated from each other, the pixel insulation structure 330 does not gap-fill the spaces between the first and fourth pixel group isolation structures (341, 344), but may be configured such that a recess depth where the pixel insulation structure 330 is recessed from the second surface 820 (or the first surface 810 according to another embodiment) into the semiconductor substrate 800 is smaller than a recess depth where the first and fourth pixel group isolation structures (341, 344) are recessed into the semiconductor substrate 800, and is also greater than a recess depth where the insulation trench structure 510 is recessed into the semiconductor substrate 800.

For example, two trenches (e.g., first and second trenches) recessed from the second surface 820 into the semiconductor substrate 800 may be formed. After removing the area between the first and second trenches to a depth smaller than those of the two trenches, a layer including the insulation material may be formed in a region (e.g., an etched region) from which the semiconductor substrate 800 has been removed, resulting in formation of the pixel insulation structure 330. After the pixel insulation structure 330 is formed, the first and second trench regions may be gap-filled to form the first pixel group isolation structure 341 and the fourth pixel group isolation structure 344. Then, a trench (e.g., a third trench) formed when the first and fourth pixel group isolation structures (341, 344) and the pixel insulation structure 330 are partially removed may be formed to be recessed from the second surface 820. For example, the third trench may be gap-filled with the same material as the pixel insulation structure 330, resulting in formation of the insulation trench structure 510.

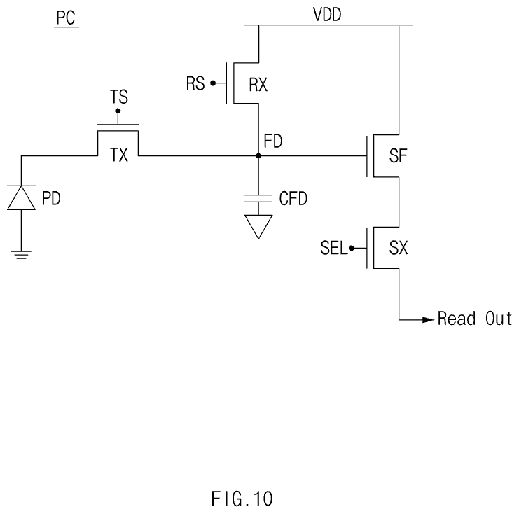

FIG. 10 is a circuit diagram illustrating an example of a pixel circuit (PC) configured to model each pixel shown in FIG. 2 according to embodiments of the disclosed technology.

Referring to FIGS. 2 and 10, a pixel circuit (PC) may include a photoelectric conversion element (PD), a transfer transistor (TX), a floating diffusion region (FD), a reset transistor (RX), a source follower transistor (SF), and a selection transistor (SX). The pixel circuit (PC) is a circuit diagram modeling each pixel. For example, each of the first to sixteenth pixels (PX1˜PX16) of FIG. 3 or FIG. 4 may be modeled as the same circuit diagram.

The photoelectric conversion element (PD) may receive and absorb incident light, and may generate photocharges corresponding to the intensity of incident light through photoelectric conversion of the incident light. For example, the photoelectric conversion element (PD) may be implemented as a photodiode, a phototransistor, a photogate, or a combination thereof. In FIG. 10, the photoelectric conversion element (PD) is exemplarily illustrated as a photodiode as the example for convenience of description.

The transfer transistor (TX) may be a transistor having a gate electrode to which a voltage corresponding to a row transfer signal (TS) is applied. The transfer signal (TS) may have any one of a high level and a low level. The transfer transistor TX may be turned on in response to the transfer signal (TS) having a high level, and may be turned off in response to the transfer signal (TS) having a low level. When the transfer transistor (TX) is turned on, photocharges generated by the photoelectric conversion element (PD) may move to the floating diffusion region (FD). A source electrode of the transfer transistor (TX) may be, for example, a photoelectric conversion element (PD). A drain electrode of the transfer transistor (TX) may be, for example, a floating diffusion region (FD).

The floating diffusion region (FD) may accumulate photocharges introduced by moving from the photoelectric conversion element (PD) through the transfer transistor (TX). The floating diffusion region (FD) may serve to convert photocharges into a voltage. Since the floating diffusion region (FD) has a junction capacitor, the floating diffusion region (FD) can be used as a region in which photocharges can be accumulated. For example, the floating diffusion region (FD) may be a region containing impurities of a first conductivity type, and a semiconductor layer (e.g., the semiconductor substrate 600 of FIGS. 6 and 7 or the semiconductor substrate 800 of FIGS. 8 and 9) surrounding the floating diffusion region FD may be a region containing impurities of a second conductivity type. Here, the floating diffusion region (FD) may include a floating capacitor (CFD).

A reset transistor (RX) may be a transistor having a gate electrode to which a voltage corresponding to a reset signal (RS) is applied. The reset signal (RS) may have any one of a high level and a low level. The reset transistor (RX) may be turned on in response to the reset signal (RS) having a high level, and may be turned off in response to the reset signal (RS) having a low level. When the reset transistor (RX) is turned on, the floating diffusion region (FD) may be reset to a power-supply voltage (VDD). A source electrode of the reset transistor (RX) may be, for example, a floating diffusion region (FD). A drain electrode of the reset transistor (RX) may be, for example, the power-supply voltage (VDD).

A source follower transistor (SF) may amplify a potential change of the floating diffusion region (FD) and may transmit the amplified potential change to the selection transistor (SX). A voltage caused by photocharges accumulated in the floating diffusion region (FD) may be applied to the gate electrode of the source follower transistor (SF). The source electrode of the source follower transistor (SF) may be connected to the power-supply voltage (VDD). The drain electrode of the source follower transistor (SF) may be connected to the source electrode of the select transistor (SX).

The selection transistor (SX) may be a transistor having a gate electrode to which a voltage corresponding to the selection signal (SEL) applied. The selection signal (SEL) may have a high level or a low level. The selection transistor (SX) may be turned on in response to the selection signal (SEL) having a high level, and may be turned off in response to the selection signal (SEL) having a low level. When the selection transistor (SX) is turned on, a pixel signal corresponding to a change in potential of the floating diffusion region (FD) amplified by the source follower transistor (SF) may be output. The series of processes for outputting the pixel signal from the selection transistor (SX) may be an example of a pixel readout process. The output pixel signal may be transmitted to the correlated double sampler (CDS) 130 as described in FIG. 1.

For example, an example of a pixel readout process is as follows.

The transfer transistor (TX) may move photocharges generated by the photoelectric conversion element or photodetector (PD) to the floating diffusion region (FD) in response to the transfer signal (TS) having a high level. The source follower transistor (SF) may amplify the potential change corresponding to photocharges accumulated in the floating diffusion region (FD). The selection transistor (SX) may generate a pixel signal corresponding to the potential change amplified by the source follower transistor (SF) in response to the selection signal (SEL) having a high level.

During the readout time period of the pixel, for example, the selection signal (SEL) may have a high level. The readout period may refer to a time period in which the pixel readout process is performed.

FIG. 11A is a timing diagram illustrating example levels of first to fourth bias signals (BS1˜BS4) applied to first to fourth pixel isolation structures (321˜324) shown in FIG. 5A according to embodiments of the disclosed technology.

FIG. 11B is a timing diagram illustrating example levels of first to fourth bias signals (BS1˜BS4) applied to first to fourth pixel group isolation structures (341˜344) shown in FIG. 5B according to embodiments of the disclosed technology.

Referring to FIGS. 3, 5A, 10, and 11A, the first to sixteenth pixels (PX1˜PX16) of the first pixel group 200G1 may be arranged in a (4×4) matrix structure. The first, second, fifth, and sixth pixels (PX1, PX2, PX5, PX6) may be arranged in one row (e.g., a first row line). The third, fourth, seventh, and eighth pixels (PX3, PX4, PX7, PX8) may be arranged in another row (e.g., a second row line). The ninth, tenth, thirteenth, and fourteenth pixels (PX9, PX10, PX13, PX14) may be arranged in another row (e.g., a third row line). The eleventh, twelfth, fifteenth, and sixteenth pixels (PX11, PX12, PX15, PX16) may be arranged in another row (e.g., a fourth row line).

A section in which readout for the first row line is performed may be a first readout section (RO1). A section in which readout for the second row line is performed may be a second readout section (RO2). A section in which readout for the third row line is performed may be a third readout section (RO3). A section in which readout for the fourth row line is performed may be a fourth readout section (RO4).

The first readout period (RO1) may be a period denoted by [t1, t2] (where t1<t2). The second readout period (RO2) may be a period denoted by [t3, t4] (where t2<t3<t4). The third readout period (RO3) may be a period denoted by [t5, t6] (where t4<t5<t6). The fourth readout period (RO4) may be a period denoted by [t7, t8] (where t6<t7<t8).

The bias voltage generator 300 may generate first to fourth bias signals (BS1˜BS4), respectively. Each of the first to fourth bias signals (BS1˜BS4) may have a high level (H) or a low level (L) depending on time.

A first bias signal (BS1) may have a high level (H) in each of the first readout period (RO1) and the third readout period (RO3). The first bias signal (BS1) may have a low level (L) in each of the second readout period (RO2) and the fourth readout period (RO4). In each of the first and third readout sections (RO1, RO3) in which the first bias signal (BS1) has a high level (H), the bias voltage generator 300 may apply a first bias voltage (VD1) to the first pixel isolation structure 321. In a section in which the first bias signal (BS1) has a low level (L), the bias voltage generator 300 may not apply the first bias voltage (VD1) to the first pixel isolation structure 321.

A second bias signal (BS2) may have a high level (H) in each of the first readout period (RO1) and the third readout period (RO3). The second bias signal (BS2) may have a low level (L) in each of the second readout period (RO2) and the fourth readout period (RO4). In each of the first and third readout sections (RO1, RO3) in which the second bias signal (BS2) has a high level (H), the bias voltage generator 300 may apply a second bias voltage (VD2) to the second pixel isolation structure 322. In a section in which the second bias signal (BS2) has a low level (L), the bias voltage generator 300 may not apply the second bias voltage (VD2) to the second pixel isolation structure 322.

A third bias signal (BS3) may have a high level (H) in each of the second readout period (RO2) and the fourth readout period (RO4). The third bias signal (BS3) may have a low level (L) in each of the first readout period (RO1) and the third readout period (RO3). In each of the second and fourth readout sections (RO2, RO4) in which the third bias signal (BS3) has a high level (H), the bias voltage generator 300 may apply a third bias voltage (VD3) to the third pixel isolation structure 323. In a section in which the third bias signal (BS3) has a low level (L), the bias voltage generator 300 may not apply the third bias voltage (VD3) to the third pixel isolation structure 323.

A fourth bias signal (BS4) may have a high level (H) in each of the second readout period (RO2) and the fourth readout period (RO4). The fourth bias signal (BS4) may have a low level (L) in each of the first readout period (RO1) and the third readout period (RO3). In each of the second and fourth readout sections (RO2, RO4) in which the fourth bias signal (BS4) has a high level (H), the bias voltage generator 300 may apply a fourth bias voltage (VD4) to the fourth pixel isolation structure 324. In a section in which the fourth bias signal (BS4) has a low level (L), the bias voltage generator 300 may not apply the fourth bias voltage (VD4) to the fourth pixel isolation structure 324.

The first to fourth bias voltages (VD1˜VD4) may not be applied to the pixel isolation structures at a specific time point where the first to fourth bias signals (BS1˜BS4) have a low level (L), the image sensing device 100 based on some implementations of the disclosed technology can reduce power consumption required when bias voltages are applied to reduce noise.

Among the embodiments of the disclosed technology described in FIG. 3, in an embodiment in which the first color is green, the second color is red, and the third color is blue, the first bias voltage (VD1) may be higher than the second bias voltage (VD2) and the second bias voltage (VD2) may be higher than the third bias voltage (VD3). In an embodiment in which the fourth color is green, the fourth bias voltage (VD4) may be higher than each of the second bias voltage (VD2) and the third bias voltage (VD3). In an embodiment in which the fourth color is white, the fourth bias voltage (VD4) may be higher than the first bias voltage (VD1).

The magnitude relationship between the first to fourth bias voltages (VD1˜VD4) is merely an example, may vary depending on the embodiments, and may be determined experimentally.

In FIG. 11B, descriptions overlapping with those of FIG. 11A will be omitted or simply given for convenience of description.

Referring to FIGS. 4, 5B, 10, and 11B, the first to sixteenth pixels (PX1˜PX16) of the second pixel group 200G2 may be arranged in a (4×4) matrix structure. The first, second, fifth, and sixth pixels (PX1, PX2, PX5, PX6) may be arranged in one row (e.g., a first row line). The third, fourth, seventh, and eighth pixels (PX3, PX4, PX7, PX8) may be arranged in another row (e.g., a second row line). The ninth, tenth, thirteenth, and fourteenth pixels (PX9, PX10, PX13, PX14) may be arranged in another row (e.g., a third row line). The eleventh, twelfth, fifteenth, and sixteenth pixels (PX11, PX12, PX15, PX16) may be arranged in another row (e.g., a fourth row line).

The bias voltage generator 300 may generate first to fourth bias signals (BS1˜BS4), respectively. Each of the first to fourth bias signals (BS1˜BS4) may have any one of a high level (H) and a low level (L) depending on time.

A first bias signal (BS1) may have a high level (H) in each of the first readout period (RO1) and the second readout period (RO2). The first bias signal (BS1) may have a low level (L) in each of the third readout period (RO3) and the fourth readout period (RO4). In each of the first and second readout sections (RO1, RO2) in which the first bias signal (BS1) has a high level (H), the bias voltage generator 300 may apply the first bias voltage (VD1) to the first pixel isolation structure 321. In a section in which the first bias signal (BS1) has a low level (L), the bias voltage generator 300 may not apply the first bias voltage (VD1) to the first pixel isolation structure 321.

A second bias signal (BS2) may have a high level (H) in each of the first readout period (RO1) and the second readout period (RO2). The second bias signal (BS2) may have a low level (L) in each of the third readout period (RO3) and the fourth readout period (RO4). In each of the first and second readout sections (RO1, RO2) in which the second bias signal (BS2) has a high level (H), the bias voltage generator 300 may apply the second bias voltage (VD2) to the second pixel isolation structure 322. In a section in which the second bias signal (BS2) has a low level (L), the bias voltage generator 300 may not apply the second bias voltage (VD2) to the second pixel isolation structure 322.

A third bias signal (BS3) may have a high level (H) in each of the third readout period (RO3) and the fourth readout period (RO4). The third bias signal (BS3) may have a low level (L) in each of the first readout period (RO1) and the second readout period (RO2). In each of the third and fourth readout sections (RO3, RO4) in which the third bias signal (BS3) has a high level (H), the bias voltage generator 300 may apply the third bias voltage (VD3) to the third pixel isolation structure 323. In a section in which the third bias signal (BS3) has a low level (L), the bias voltage generator 300 may not apply the third bias voltage (VD3) to the third pixel isolation structure 323.

A fourth bias signal (BS4) may have a high level (H) in each of the third readout period (RO3) and the fourth readout period (RO4). The fourth bias signal (BS4) may have a low level (L) in each of the first readout period (RO1) and the second readout period (RO2). In each of the third and fourth readout sections (RO3, RO4) in which the fourth bias signal (BS4) has a high level (H), the bias voltage generator 300 may apply the fourth bias voltage (VD4) to the fourth pixel isolation structure 324. In a section in which the fourth bias signal (BS4) has a low level (L), the bias voltage generator 300 may not apply the fourth bias voltage (VD4) to the fourth pixel isolation structure 324.

The first to fourth bias voltages (VD1˜VD4) may not be applied to the pixel isolation structures at a specific time point where the first to fourth bias signals (BS1˜BS4) have a low level (L). The image sensing device 100 based on some implementations of the disclosed technology can reduce power consumption required when bias voltages are applied to reduce noise.

Among the embodiments of the disclosed technology described in FIG. 3, in an embodiment in which the first color is green, the second color is red, and the third color is blue, the first bias voltage (VD1) may be higher than the second bias voltage (VD2), and the second bias voltage (VD2) may be higher than the third bias voltage (VD3). In an embodiment in which the fourth color is green, the fourth bias voltage (VD4) may be higher than each of the second bias voltage (VD2) and the third bias voltage (VD3). In an embodiment in which the fourth color is white, the fourth bias voltage (VD4) may be higher than the first bias voltage (VD1).

Embodiments of the image sensing device 100 described with reference to FIGS. 1 to 11B are not limited to the above-described examples. In the image sensing device 100 operates in, for example, an all-4-coupled (A4C) mode or a phase detection autofocus (PDAF) mode for adjusting the focus, a readout order of pixels included in the pixel array 200 may be determined differently from an image generation mode in which images for external scenes are generated, and either a timing point where the bias voltage is applied to the pixel isolation structures according to the readout order of pixels or the magnitude of bias voltage may also be determined differently from the image generation mode.

The image sensing device 100 according to the embodiments of the disclosed technology may independently control the bias voltage applied to each pixel isolation structure surrounding the pixel that generates a pixel signal in response to light of different colors, and may provide higher-quality images in which noise of pixels upon which light beams of different colors are incident can be more effectively reduced.

In addition, the embodiments of the disclosed technology can provide the image sensing device that adjusts a signal level of the bias voltage applied to the pixel isolation structure to reduce pixel noise, resulting in reduction in power consumption required to reduce noise of each pixel.

As is apparent from the above description, the image sensing device based on some implementations of the disclosed technology can reduce noise of pixels, and can reduce noise deviation that may occur between pixels that transmit light of different wavelengths.

The image sensing device based on some implementations of the disclosed technology can reduce power consumption by designing timing points at which different bias voltages are applied to the pixels that respectively transmit light beams of different wavelengths.

Although a number of illustrative embodiments have been described, it should be understood that modifications and enhancements to the disclosed embodiments and other embodiments can be devised based on what is described and/or illustrated in this patent document.

What is claimed is:

1. An image sensing device comprising:
a first pixel configured to overlap a first optical filter that transmits light of a first color and configured to generate photocharge in response to the light of the first color;
a second pixel disposed apart from the first pixel in a first direction and configured to overlap a second optical filter that transmits light of a second color different from the first color and to generate photocharge in response to the light of the second color;
a first pixel isolation structure surrounding the first pixel to isolate the first pixel and the second pixel from each other and configured to receive a first bias voltage; and
a second pixel isolation structure surrounding the second pixel to optically isolate the first pixel and the second pixel from each other and configured to receive a second bias voltage different from the first bias voltage.

2. The image sensing device according to claim 1, further comprising:
a first bias contact configured to transfer the first bias voltage to the first pixel isolation structure; and
a second bias contact configured to transfer the second bias voltage to the second pixel isolation structure.

3. The image sensing device according to claim 1, further comprising:
a third pixel configured to have a third optical filter that transmits light of a third color different from each of the first color and the second color, the third pixel disposed apart from the first pixel in a second direction different from the first direction; and
a third pixel isolation structure surrounding the third pixel and configured to receive a third bias voltage,
wherein
the third bias voltage is different from each of the first bias voltage and the second bias voltage.

4. The image sensing device according to claim 3, further comprising:
a third bias contact configured to transfer the third bias voltage to the third pixel isolation structure.

5. The image sensing device according to claim 3, wherein:
the first color is green, the second color is red, and the third color is blue.

6. The image sensing device according to claim 1, further comprising:
a pixel insulation structure disposed between the first pixel isolation structure and the second pixel isolation structure, and configured to electrically isolate the first pixel isolation structure and the second pixel isolation structure from each other.

7. The image sensing device according to claim 1, wherein:
a magnitude of the first bias voltage is greater than a magnitude of the second bias voltage in response to a dark current of the first pixel being greater than a dark current of the second pixel.

8. The image sensing device according to claim 1, wherein:
a magnitude of the first bias voltage is smaller than a magnitude of the second bias voltage in response to a temperature of the first pixel being higher than a temperature of the second pixel.

9. The image sensing device according to claim 1, further comprising:
a third pixel configured to overlap a third optical filter that transmits light of the first color and disposed apart from the first pixel in a second direction different from the first direction;
a fourth pixel configured to overlap a fourth optical filter that transmits light of the second color and disposed apart from the second pixel in the second direction;
a third pixel isolation structure surrounding the third pixel and configured to receive the first bias voltage; and
a fourth pixel isolation structure surrounding the fourth pixel and configured to receive the second bias voltage.

10. The image sensing device according to claim 9, wherein:
the first pixel isolation structure and the third pixel isolation structure are included in a first pixel group isolation structure and disposed to be in contact with each other; and
the second pixel isolation structure and the fourth pixel isolation structure are included in a second pixel group isolation structure and disposed to be in contact with each other.

11. The image sensing device according to claim 10, further comprising:
a pixel insulation structure disposed between the first pixel group isolation structure and the second pixel group isolation structure to electrically isolate the first pixel group isolation structure and the second pixel group isolation structure from each other.

12. The image sensing device according to claim 10, wherein:
the first pixel and the third pixel are read out within a first time period, and the second pixel and the fourth pixel are read out within a second time period; and
the first bias voltage is applied to the first pixel group isolation structure during the first time period, and the second bias voltage is applied to the second pixel group isolation structure during the second time period,
wherein
an end point of the first time period is earlier than a starting point of the second time period.

13. The image sensing device according to claim 1, wherein:
the first bias voltage is applied to the first pixel isolation structure during a readout of the first pixel; and
the second bias voltage is applied to the second pixel isolation structure during a readout of the second pixel.

14. An image sensing device comprising:
a first photoelectric conversion element disposed in a semiconductor substrate and configured to generate photocharges in response to incident light;
a second photoelectric conversion element disposed in the semiconductor substrate and spaced apart from the first photoelectric conversion element in a first direction, the second photoelectric conversion element configured to generate photocharges in response to the incident light;
a first optical filter disposed on a back surface of the semiconductor substrate upon which the incident light is incident and overlapping the first photoelectric conversion element, the first optical filter configured to transmit light of a first color from among the incident light;
a second optical filter disposed on the back surface of the semiconductor substrate and overlapping the second photoelectric conversion element, the second optical filter configured to transmit light of a second color different from the first color from among the incident light;
a first pixel isolation structure recessed into the semiconductor substrate and surrounding the first photoelectric conversion element; and
a second pixel isolation structure recessed into the semiconductor substrate and surrounding the second photoelectric conversion element,
wherein
the first pixel isolation structure is configured to receive a first bias voltage; and
the second pixel isolation structure is configured to receive a second bias voltage different from the first bias voltage.

15. The image sensing device according to claim 14, further comprising:
a third photoelectric conversion element disposed within the semiconductor substrate and spaced apart from the first photoelectric conversion element in a second direction different from the first direction, the third photoelectric conversion element configured to generate photocharges in response to the incident light; and
a third optical filter disposed on the back surface of the semiconductor substrate and overlapping the third photoelectric conversion element, the third optical filter configured to transmit light of a third color different from each of the first color and the second color from among the incident light.

16. The image sensing device according to claim 15, wherein:
the first color is green, the second color is red, and the third color is blue.

17. The image sensing device according to claim 15, further comprising:
a third pixel isolation structure recessed into the semiconductor substrate and surrounding the third photoelectric conversion element, the third pixel isolation structure spaced apart from the first pixel isolation structure in the second direction,
wherein
the third pixel isolation structure is configured to receive a third bias voltage different from each of the first bias voltage and the second bias voltage.

18. The image sensing device according to claim 14, further comprising:
a pixel insulation structure disposed between the first pixel isolation structure and the second pixel isolation structure to electrically isolate the first pixel isolation structure and the second pixel isolation structure from each other.

19. An image sensing device comprising:
a first pixel configured to generate an electrical signal in response to light of a first color;
a second pixel spaced apart from the first pixel and configured to generate an electrical signal in response to light of a second color;
a first pixel isolation structure configured to receive a first bias voltage and surrounding the first pixel; and
a second pixel isolation structure spaced apart from the first pixel isolation structure, and configured to receive a second bias voltage and surrounding the second pixel.

20. An image sensing device comprising:
a first pixel group including a plurality of first pixels, each first pixel configured to generate an electrical signal in response to light of a first color;
a second pixel group including a plurality of second pixels, each second pixel configured to generate an electrical signal in response to light of second color;
a first pixel group isolation structure configured to receive a first bias voltage and surrounding the plurality of first pixels; and
a second pixel group isolation structure spaced apart from the first pixel group isolation structure and surrounding the plurality of second pixels, the second pixel group isolation structure configured to receive a second bias voltage.
